(19) United States
(12) Patent Application Publication
(10) Pub. No.: US 2006/0050744 A1
(43) Pub. Date: Mar. 9, 2006

(54) Enhanced raman amplification and lasing in silicon-based photonic crystals

(75) Inventors: Chee Wei Wong, New York, NY (US); Xiadong Yang, New York, NY (US)

Correspondence Address: WILMER CUTLER PICKERING HALE AND DORR LLP, 399 PARK AVENUE, NEW YORK, NY, 10022, US

(73) Assignee: The Trustees of Columbia University in the City of New York, New York, NY (US)

(21) Appl. No.: 11/185,031

(22) Filed: Jul. 20, 2005

Related U.S. Application Data
(60) Provisional application No. 60/589,903, filed on Jul. 20, 2004.

(51) Int. Cl. H01S 3/30; H01S 5/00

(52) U.S. Cl. 372/3; 372/46.01

(57) ABSTRACT

Tunable laser devices and methods of manufacturing such devices are disclosed. air-holes with defects that form an optical waveguide. The waveguide has a cross-sectional area whose dimensions are in sub-wavelength ranges, wherein the cross-sectional area is perpendicular to the propagation direction of light in the waveguide. The waveguide receives pump light and outputs Stokes light through Raman scattering. The laser device may include a photonic crystal made from silicon having air-holes with defects forming a pair of optically coupled cavities. The geometries of the cavities can be substantially identical to each other. The cavities are defined to cause a frequency-splitting difference between a frequency of pump light and a frequency of Stokes light to correspond to an optical phonon frequency in silicon through Raman scattering.

### RELATED APPLICATION

This application claims the priority of U.S. Provisional Application 60/589,903 filed on Jul. 20, 2004, which is incorporated herein by reference in its entirety.

### FIELD OF THE INVENTION

This invention relates to Raman microlasers using photonic crystals made from silicon to achieve low-loss, low-threshold Raman lasing.

### BACKGROUND OF THE INVENTION

Stimulated Raman scattering (SRS) has a rich and evolving history since the development of the laser. In 1962, Woodbury and Ng discovered the SRS effect at infrared frequencies. [E. J. Woodbury and W. K. Ng, Proc. IRE 50, 2347 (1962)] Hellwarth quickly described this observation as a two-photon process with a full quantum mechanical calculation. [R. W. Hellwarth, Theory of Stimulated Raman Scattering, Phys. Rev. 130, 1850 (1963)] To account for anti-Stokes generation and higher-order Raman effects, however, Garnmire et al. and Bloembergen and Shen then adopted the coupled-wave formalism to describe the stimulated Raman effect. [E. Garmire, E. Pandarese, and C. H. Townes, Coherently Driven Molecular Vibrations and Light Modulation, Phys. Rev. Lett. 11, 160 (1963); N. Bloembergen and Y. R. Shen, Coupling Between Vibrations and Light Waves in Raman Laser Media, Phys. Rev. Lett. 12, 504 (1964); Y. R. Shen and N. Bloembergen, Theory of Stimulated Brillouin and Raman Scattering, Phys. Rev. 137, A1787 (1965)] These understandings were later improved by the inclusion of self-focusing to account for the much larger gain observed in SRS.

Recent developments include coupling a high Q (“Q” is a quality factor) silica microsphere to an optical fiber to achieve a minimum threshold of 62 μW, an example of which is illustrated in FIG. 1A. [S. M. Spillane, T. J. Kippenberg, and K. J. Vahala, Ultralow-threshold Raman laser using a spherical dielectric microcavity, Nature 415, 621 (2002)] Higher-order Raman modes were observed in addition to other nonlinearities such as four-wave mixing and stimulated Brillouin scattering.

In a different line of researches that does not use SRS, various researches have demonstrated that a laser-reflowed silicon oxide microresonator with additional Er³⁺ doping can achieve low-threshold lasing. [A. Polman, B. Min, J. Kalkman, T. J. Kippenberg, and K. J. Vahala, Ultralow-threshold erbium-implanted toroidal microlaser on silicon, App. Phys. Lett. 84 (7), 1037, 2004)] Concurrently, Claps et al. have demonstrated a small but first-ever Raman amplification in silicon on-chip waveguides for photonic integrated circuit applications. [R. Claps, D. Dimitropoulos, V. Raghunathan, Y. Han, and B. Jalali, Observation of stimulated Raman amplification in silicon waveguides, Optics Express 11 (15), 1731 (2003)] FIG. 1B illustrates an example of such a waveguide that is a centimeter long.

However, presently, the development of sizable gain in silicon photonic integrated circuits has yet to be demonstrated. This is suspected due to un-optimized phase matching design of the optical structures. [R. H. Stolen and E. P. Ippen, Raman gain in glass optical waveguides, App. Phys. Lett. 22 (6), 276 (1973)]

### SUMMARY OF THE INVENTION

Various embodiments of the present invention provide tunable laser devices and methods of manufacturing such devices. In particular, the laser device may include a layer of photonic crystal having a lattice of air-holes with defects that form an optical waveguide. The waveguide has a cross-sectional area whose dimensions are in sub-wavelength ranges, wherein the cross-sectional area is perpendicular to the propagation direction of light in the waveguide. The waveguide receives pump light and outputs Stokes light through Raman scattering. The frequencies of the pump light and the Stokes light can be selected from slow group velocity modes of the pump light and Stokes light in the waveguide. The slow group velocity can be about 1/100 of the speed of light.

The waveguide can be integrated with CMOS microelectronic devices. For instance, a p-i-n (p-type, intrinsic, n-type) diode can be integrated with the waveguide to achieve a continuous wave lasing in the optical waveguide. The waveguide can also receive pulsed pump light.

In some embodiments, the waveguide may include a pair of optically coupled cavities, whose geometries are substantially identical to each other. The cavities can be defined to cause a frequency-splitting difference between a frequency of the pump light and a frequency of the Stokes light to correspond to an optical phonon frequency in silicon for Raman scattering lasing or amplification. The optical phonon frequency is about 15.6 THz in single-crystal silicon at the room temperature.

A one-dimensional photonic crystal shaped like a bar can also form the laser device. In such embodiments, air-holes with defects can form cavities. Fabrication processes to manufacture various embodiments of the present invention are also described.

### BRIEF DESCRIPTION OF THE DRAWINGS

Embodiments of the present invention will be best understood when read in reference to the accompanying figures wherein:

FIG. 1A is a magnified view of a conventional microsphere made from silica;

FIG. 1B is a magnified view of a conventional waveguide having its modal area of approximately 2-4 μm² and the length of approximately 10,000 μm;

FIG. 2 is a magnified view of an example photonic crystal with a waveguide manufactured in accordance with various embodiments of the present invention;

FIG. 3 is a graphical illustration of a relationship between pump light, Stokes light, and phonons in Raman scattering;

FIG. 4 is a graphical illustration of a calculated band structure depicting possible guided modes;

FIG. 4A is a magnified view of a portion of FIG. 4;

FIG. 5 is a magnified view of an example photonic crystal with a bar-like structure manufactured in accordance with various embodiments of the present invention;

FIG. 6 is a magnified view of an example photonic crystal with a bar-like structure with a p-i-n diode manufactured in accordance with various embodiments of the present invention;

FIG. 7A is a magnified top view showing a pump mode response of an example photonic crystal with a bar-like structure manufactured in accordance with various embodiments of the present invention;

FIG. 7B is a magnified top view showing a Stokes mode response of an example photonic crystal with a bar-like structure manufactured in accordance with various embodiments of the present invention;

FIG. 8 is a graphical illustration of pump and Stokes mode frequency responses of an example photonic crystal with a bar-like structure manufactured in accordance with various embodiments of the present invention;

FIG. 9 is a magnified view of an example two-dimensional (2D) photonic crystal with a pair of coupled microcavities manufactured in accordance with various embodiments of the present invention;

FIG. 10 is a magnified view of an example 2D photonic crystal with a pair of coupled microcavities with a p-i-n diode manufactured in accordance with various embodiments of the present invention;

FIG. 11 is a magnified view of an example 2D photonic crystal functioning as an amplifier with a pair of coupled microcavities manufactured in accordance with various embodiments of the present invention;

FIG. 12 is a magnified top view of an example 2D photonic crystal functioning as an amplifier with a microcavity manufactured in accordance with various embodiments of the present invention;

FIG. 12A is a graphical illustration of a frequency response with a light cone for an example 2D photonic crystal of FIG. 12;

FIG. 13 is a magnified top view of another example 2D photonic crystal functioning as an amplifier with a microcavity manufactured in accordance with various embodiments of the present invention;

FIG. 14 is a graphical illustration showing two defect modal frequencies when a Gaussian impulse is launched at the center for an embodiment illustrated in FIG. 13;

FIG. 15 is a graphical illustration comparing quality factors of the pump mode and Stokes mode for different shifts of two air holes for an embodiment illustrated in FIG. 13;

FIG. 16 is a magnified top view of an example 2D photonic crystal having one-mode waveguides manufactured in accordance with various embodiments of the present invention; and

FIG. 17 is a block diagram illustrating various components for using pulsed pump light in various embodiments of the present invention.

### DETAILED DESCRIPTION OF EMBODIMENTS OF THE PRESENT INVENTION

SRS is a linear inelastic two-photon process, where an incident photon interacts with an excited state of the material. In various embodiments of the present invention, which include the use of photonic crystals made of silicon, the excited state of the material refers to the longitudinal optical (LO) and transversal optical (TO) phonons of crystal silicon. In such embodiments, the strongest Stokes peak arises from single first-order Raman-phonon (threefold degenerate) at the Brillouin zone center of silicon. A microscopic description that depicts the change in the average number of photons nₛ at the Stokes wavelength ωₛ with respect to the longitudinal distance z is:

$${}^{\frac{ⅆ {n}_{s}}{ⅆ z}} = ( {G}_{R} - {α}_{s} ) {n}_{s} , {G}_{R} = {}_{}^{\frac{ⅆ {W}_{fi}}{ⅆ {ω}_{s}}}{( {ρ}_{i} - {ρ}_{f} )}{}_{}^{\frac{1}{{μ}^{1 / 2} {n}_{s}}} , \qquad ( 1 )$$

where G_{R} is the Raman gain, αₛ an attenuation coefficient, μ the permeability,

$$\frac{ⅆ {W}_{fi}}{ⅆ {ω}_{s}}$$

the transition rate, and ρᵢ and ρ_{f} the initial and final state populations, respectively. For nₛ and nₚ (the average number of photons at ωₚ) significantly greater than 1,

$${}^{\frac{ⅆ {W}_{fi}}{ⅆ {ω}_{s}}} ∝ {n}_{s} {n}_{p}$$

and thus the Raman gain G_{R} is ∝ nₚ. For large nₛ and nₚ, a mesoscopic classical description with Maxwell equations using nonlinear polarizations P⁽³⁾ can also be used. The wave equations describing the interactions are:

$$\begin{matrix}∇ \times ( ∇ \times {E}_{s} ) + {}^{\frac{1}{{c}^{2}} \frac{{\partial }^{2}}{\partial {t}^{2}}} ( {ɛ}_{s} {E}_{s} ) = - {}^{\frac{1}{{c}^{2}} \frac{{\partial }^{2}}{\partial {t}^{2}}} ( {P}_{s}^{( 3 )} ) & ( 2 ) \\ ∇ \times ( ∇ \times {E}_{p} ) + {}^{\frac{1}{{c}^{2}} \frac{{\partial }^{2}}{\partial {t}^{2}}} ( {ɛ}_{p} {E}_{p} ) = - {}^{\frac{1}{{c}^{2}} \frac{{\partial }^{2}}{\partial {t}^{2}}} ( {P}_{p}^{( 3 )} ) . & ( 3 )\end{matrix}$$

Specifically, Pₛ⁽³⁾=χⱼₖₘₙ⁽³⁾EₚE*ₚEₛ, where χⱼₖₘₙ⁽³⁾ is the third-order fourth-rank Raman susceptibility with {j,k,m,n}={x,y,z}. The resonant terms in Pₛ⁽³⁾ give rise to SRS, while the non-resonant terms add to self-focusing and field-induced birefringence. The Eₚ and Eₛ are the electric fields at the pump and Stokes wavelengths, respectively. With χⱼₖₘₙ⁽³⁾ obtained from bulk material properties, Equations (2) and (3) can be turned into discrete forms in the time-domain for direct ab initio numerical calculations of the nonlinear response.

As an approximation to the direct solution of this wave interpretation, the coupled-mode theory can be used to estimate the stimulated Raman gain. In particular, under the assumption of weak coupling between the pump and Stokes waves, the mode amplitudes can be given as:

$$\begin{matrix}\frac{\partial {E}_{p}}{\partial \underline{z}} = - ⅈ {β}_{pp} {I}_{p} {E}_{p} & ( 4 ) \\ \frac{\partial {E}_{s}}{\partial \underline{z}} = - ⅈ ( {β}_{p s} ( {ω}_{s} ) + {κ}_{p s} ( {ω}_{s} ) ) {I}_{p} {E}_{s} - ⅈ ( {β}_{pa} ( {ω}_{s} ) + {κ}_{pa} ( {ω}_{s} ) ) {E}_{p}^{2} {E}_{a}^{*} {ⅇ}^{- ⅈ Δ kz} & ( 5 ) \\ \frac{\partial {E}_{a}}{\partial \underline{z}} = - ⅈ ( {β}_{pa} ( {ω}_{a} ) + {κ}_{pa} ( {ω}_{a} ) ) {I}_{p} {E}_{a} - ⅈ ( {β}_{p s} ( {ω}_{a} ) + {κ}_{p s} ( {ω}_{a} ) ) {E}_{p}^{2} {E}_{s}^{*} {ⅇ}^{- ⅈ Δ kz} & ( 6 )\end{matrix}$$

where the self-coupling terms are neglected, Eₚ, Eₛ and Eₐ denote the pump, and Stokes and anti-Stokes field amplitudes are denoted, respectively, as Iₚ=|Eₚ|², Iₛ=|Eₚ|². β_{ab} denotes the non-resonant terms and resonant terms with no frequency dependence. κ_{ab} denotes the resonant overall coupling coefficients (integrated spatially) between the modes. By determining κₚₛ(ωₛ) Equations (4) and (5) can be employed to determine the SRS gain. Intrinsic loss due to two-photon absorption (TPA) is assumed to be small based on the measured TPA coefficients in silicon and at pump powers on the order of 1 W. The role of TPA-induced free carrier absorption is also reduced in sub-wavelength silicon-on-insulator (SOI) waveguides of various embodiments of the present invention due to significantly shorter lifetime (compared to the recombination lifetime). This results in lower overall carrier densities.

Dimitropoulos et al. have derived a specialized form of Equations (5) to determine the Raman gain G_{R} in waveguides. [D. Dimitropoulos, B. Houshmand, R. Claps, and B. Jalali, Coupled-mode theory of the Raman effect in silicon-on-insulator waveguides, Optics Lett. 28 (20), 1954 (2003)] In particular, G_{R} has an approximate 1/(modal area)^{3/4} dependence; that is, the SRS gain increases with decreasing modal areas, such as from high-index contrast waveguide structures. In various embodiments of the present invention, as will be described in detail later, enhancements through smaller modal areas Aₘ and length scales x, Purcell enhancements and/or slow group velocities afforded by photonic crystal structures permit increased amplification with significantly smaller device length scales.

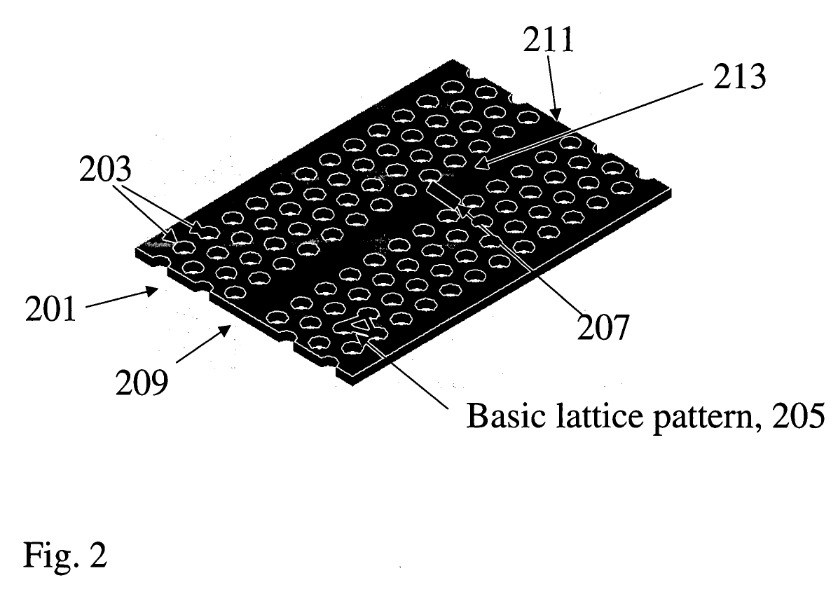

An example photonic crystal 201 manufactured in accordance with various embodiments of the present invention is illustrated in FIG. 2. In particular, the photonic crystal 201 is formed from a layer of silicon on an insulator layer (e.g., a layer of oxide, SiO₂) (not shown). The layer of silicon can be formed by any known semiconductor fabrication method. For example, the layer of silicon can be deposited or grown on the layer underneath it. In another example, a prefabricated wafer that has a silicon layer already formed on an oxide layer can be used. A lattice of air-holes 203 is formed by etching the silicon layer. Although FIG. 2 illustrates the air-holes having a cylindrical shape, the air-holes can be in other shapes (e.g., rectangular, ellipsoidal, etc.) for some embodiments. The air-holes are not required to form perfect cylindrical shapes. The air-holes can have rough edges typically introduced during fabrication processes. The depth of the air-holes can be substantially equal to the thickness of the silicon layer (e.g., 300 nm). However, the air-holes can be shallower or deeper than the silicon layer. The etching of the silicon layer can be achieved by any known method (e.g., plasma etching, wet etching, etc.).

The lattice of air-holes also forms basic patterns 205. The example in FIG. 2 illustrates the basic lattice as having a triangular shape. However, the lattice can be formed using other basic patterns (e.g., squares, rectangles, pentagons, etc.). The etching step also creates defects (e.g., areas with no air-holes) in the lattice. In FIG. 2, the defects form a line of air-hole free region that is a pathway, which is an optical waveguide 207. Typically, a waveguide means optically transparent or low attenuation material that is used for the transmission of signals with light waves. As used in connection with various embodiments of the present invention, a waveguide is also capable of lasing using Raman scattering.

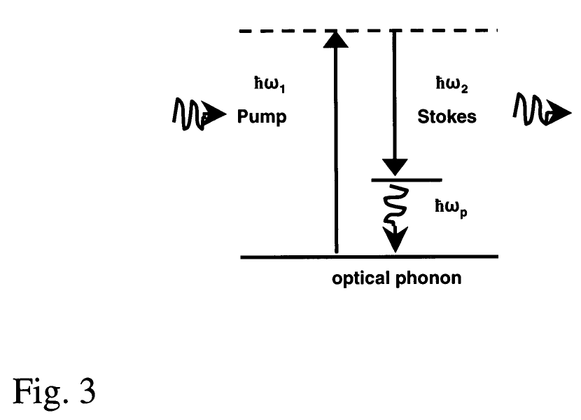

The Raman scattering is further described using the example waveguide 207 shown in FIG. 2. A light pump (not shown) coupled to the waveguide 207 supplies a beam of light (hereinafter the pump light) to an input port 209 of the waveguide 207. The pump light has a certain frequency and a corresponding wavelength. As the pump light enters and travels to an output port 211 of the waveguide 207, the pump light is downshifted (e.g., slows down) to become Stokes light, as well as causing phonons to appear. The production of Stokes light and phonons from the pump light is referred to as Raman scattering. The relationship between the pump light, Stokes light, and phonons is graphically illustrated in FIG. 3.

FIG. 2 is a magnified view of an example photonic crystal. In fact, photonic crystals of various embodiments of the present invention have lengths on order of micrometers. For instance, the length can be between 2-3 micrometers. In some embodiments, the length can be 2.5 micrometers. However, the length can be shorter or longer than these example ranges depending on the overall design of each photonic crystal. Regarding the waveguide 207, its length (i.e., the distance between the input port 209 and output port 211) can be as co-extensive as that of the photonic crystal 201. A rectangular cross-sectional area 213 of the waveguide 207 perpendicular to the propagation direction of light in the waveguide 207 (i.e., from the input port 209 to the output port 211) is preferably on order of sub-wavelength. Such a cross-sectional area is also referred to as a model area. Here, sub-wavelength refers to lengths shorter than the wavelength of a light beam (either the pump light or the Stokes light), which is approximately 1.5 micrometers. In other words, each side of the rectangular cross-section 213 of the waveguide 207 is shorter than the wavelength of a light beam. In some embodiments, the rectangular cross-sectional area is on order of sub-microns. This means each side of the rectangular cross-section of the waveguide is shorter than a micron.

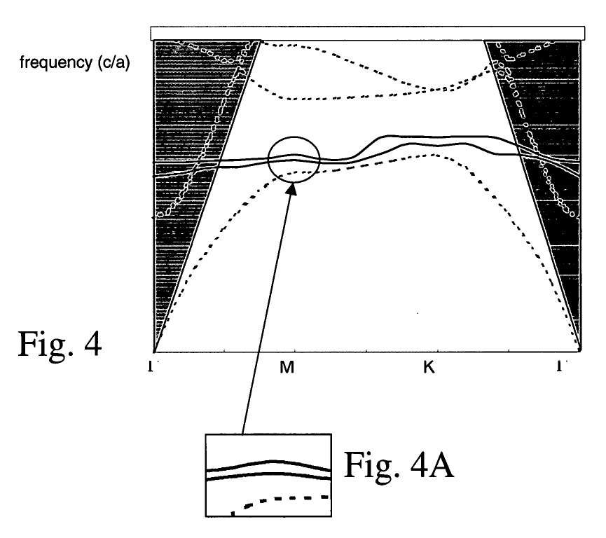

The small cross-sectional area of the waveguide 207 causes optical field densities to increase and causes the gain of the Raman scattering and lasing to increase as well. In addition to this enhancement, various embodiments of the present invention take advantage of slow light phenomena. That is, at the photonic band edge, photons experience multiple reflections and move very slowly through the material structure. In photonic crystal structures, line-defects in the periodic lattice permit guided-mode bands within the band gap, as shown in FIG. 4. In various embodiments of the present invention, these bands are designed to be as flat as possible (v_{g}≡dω/dk) to achieve slow-light behavior, shown in FIG. 4A. Group velocities as low as 10⁻² c can be obtained (“c” is the speed of light). Alternatively, coupled resonator optical waveguides can also permit control on the group velocity dispersion.

With slow group velocities, it is possible to reduce the interaction length by (v_{g}/c)². In particular, for group velocities on order of 10⁻² c, interaction lengths—between the Stokes and pump modes, for example—on order of 10⁴ times smaller than conventional lasers can be obtained. For the same operation power, the same gain can be obtained by the time-averaged Poynting power density P (˜v_{g} ε|E|²) incident on the photonic crystal structure. A decrease in v_{g} leads to a corresponding increase in ε|E|² and in the Raman gain coefficient. These line-defect waveguides can be designed for two modes (i.e., the pump and Stokes modes) to be supported within the band gap of various embodiments of the present invention.

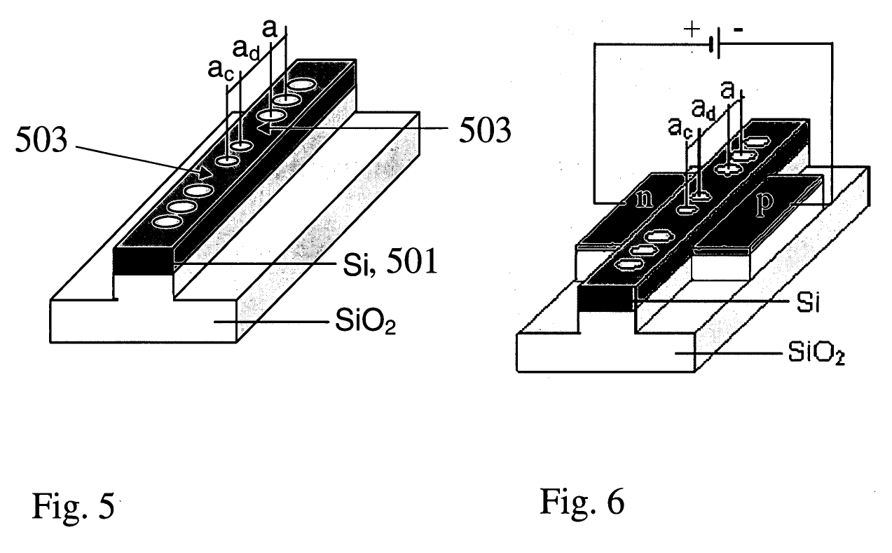

Instead of using a lattice of air-holes to form photonic crystals, as shown in FIG. 2, a photonic crystal 501 can be formed by etching a layer of silicon into a bar-like shape as illustrated in FIG. 5. For this example embodiment, a number of air-holes can be etched into the photonic crystal with defects forming a pair of optically coupled cavities 503. Since these cavities are micron sized, they are also referred to as microcavities. The single-crystal silicon provides an additional 10⁴ increase in bulk Raman gain (order 20-70 cm/GW) compared with a silica material system. The silicon-on-insulator (SOI) waveguide 501, as shown in FIG. 5, has a modal area on order of sub-wavelength or sub-micron (e.g., 0.15 μm²).

Moreover, microcavities further enhance the same waveguide geometry with the Purcell factor η and also reduce the interaction lengths (effective length≈λQ/2πn ) for an increased amplification of 10⁴. (More detailed descriptions on the Purcell factor are provided later.) This is obtained by forming two optically coupled microcavities that are formed substantially identical to each other in order to split the degenerate modes according to the strength of the coupling. Such a configuration supports both the pump and Stokes wavelengths in the microcavities, especially when they are formed in series. (Note that having two differently sized defects side-by-side in parallel requires special symmetries to force input/outputs into 2 of the 4 ports in the system.)

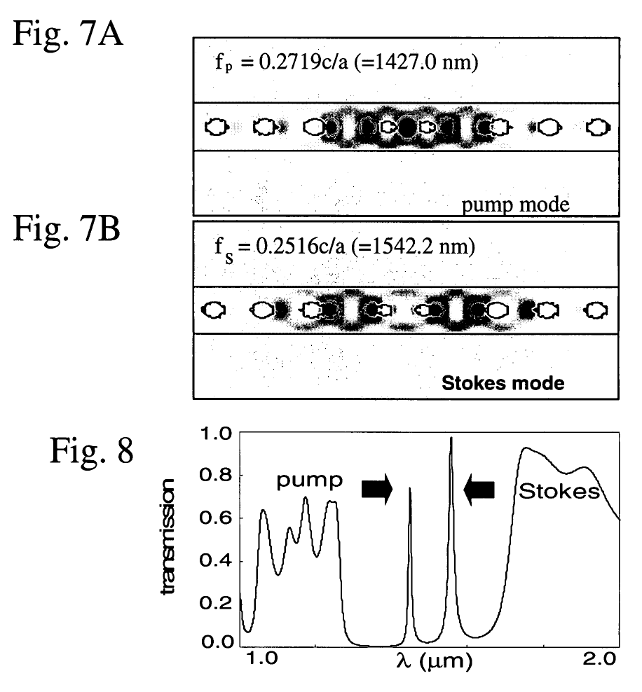

In FIG. 5, “a” is the distance between two air-holes that are not forming a microcavity, “a_{d}” is the distance between two air-holes that are forming a defect (i.e., a microcavity), and “a_{c}” is the distance between two air-holes that are formed between two microcavities. In the example shown in FIG. 5, a_{d} can be several microns wide, and the length of a microcavity between two air-holes can be on order of sub-micron (e.g., 600 nm). In turn, the entire length of the two cavities (and the two air-holes in between) shown in FIG. 5 can be 1.5 microns. By adjusting the sizes and locations of the air-holes to define the sizes and locations of the microcavities, the Stokes light (i.e., its frequency) and the pump light (i.e., its frequency) can be tuned at a certain temperature (e.g., the room temperature). In particular, the microcavities are designed to match the LO and TO phonons in silicon at room temperature. In the example illustrated in FIGS. 7A-7B, the defect resonances are spaced apart by 115 nm, with the Stokes mode operating at 1542 nm (=0.2516 c/a), where “c” is the speed of light, and the pump mode operating at 1427.0 nm (=0.2519 c/a). In other words, at the room temperature, given the frequency of the pump light with its wavelength at 1427.0 nm, the photonic crystal as illustrated in FIGS. 7A, B generates Stokes light with wavelength at 1542.2 nm.

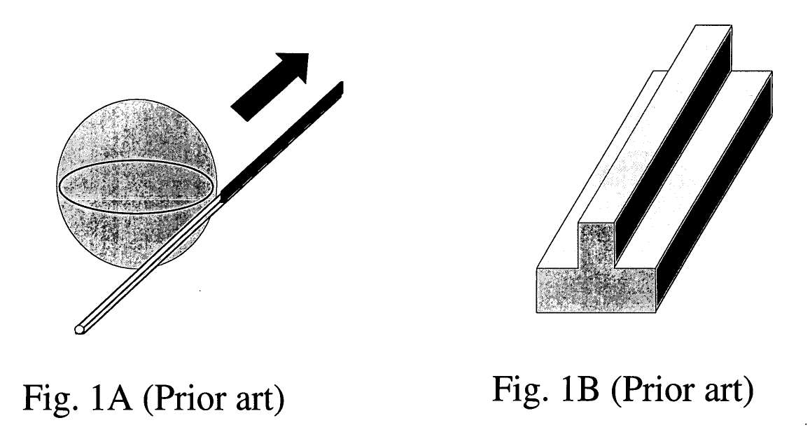

FIG. 8 shows a three-dimensional (3D) finite-difference time-domain (FDTD) computation results. Only two modes are supported in the photonic band gap (i.e., the pump and Stokes modes), and they have an overlap integral of 0.81. The pump and Stokes modes have transmissions of 0.74 and 0.97, respectively, with Q approximately 170. The pump and Stokes modes have an effective bandwidth, which can be as wide as several nanometers (nm). The photonic crystals shown in FIGS. 5 and 7A-7B achieve a Raman gain comparable to that obtainable using a centimeter long waveguide presently available (e.g., the structure shown in FIG. 1B).

More specifically, optically coupled microcavities formed in photonic crystals can obtain a good quality factor (Q) with ultra-small sub-wavelength modal volumes (Vₘ). These two factors can be perceived physically as long photon lifetimes and high field intensities per photon, respectively, contributing to microcavity-enhanced processes such as cavity quantum electrodynamics (QED) and laser physics. Placed in a cavity, the Raman phenomenon on resonance is greatly enhanced by the increased final density of states per unit volume and unit frequency. This is expressed as the Purcell factor:
η=ρ_{c}/ρₒ≈(3λ³/4π²) (Q/Vₘ) (7)
where ρ_{c} and ρₒ are the densities of states for the cavity and free space, respectively. Using microdroplets and, more recently, silica microspheres (e.g., the structure shown in FIG. 1A), Purcell factors on order of 3×10⁴ to 10⁶, respectively, have been estimated. Planar silica high Q toroid microcavities have η on order of 2×10³. Microcavities of various embodiments of the present invention also achieve η on order of 10⁴ to 10⁵. This is due to their ultra-small modal volumes (on order of 7×10⁻²⁰ m³, more than 10⁴ times smaller than conventional lasers) compensating for its lower Q (on order of 4×10⁴, more than 10⁴ times lower), in comparison with microspheres, microdroplets, or toroidal microcavities. These photonic band gap microcavities of various embodiments of the present invention can be fabricated using conventional CMOS manufacturing processes and, therefore, can form integrated circuits with conventional CMOS micro-devices (e.g., photo detectors).

The amplification gain improved by the coupled cavities is further enhanced by integrating a p-i-n (p-type, intrinsic, n-type) junction diode with the photonic crystal as illustrated in FIG. 6. In such a configuration, the strong electrical field created by the diode removes free carriers (electrons and holes). These free carriers, which are induced by two-photon absorption, can reduce, if not removed, the amplification gain factor in the photonic crystal. The p-i-n diode can be fabricated using any known semiconductor fabrication method. In operation, the diode is biased by a constant voltage.

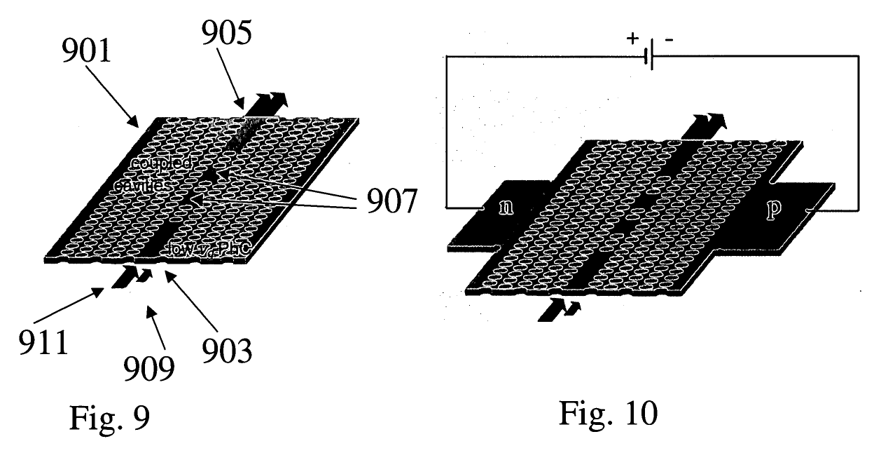

Microcavities can also be formed in a two-dimensional (2D) photonic crystal 901 as illustrated in FIG. 9. The 2D photonic crystal is made of a layer of silicon with a thickness (e.g., 300 nm) formed on a layer of insulator (e.g., a layer of oxide). Electron beam lithography can be used in combination with plasma etching to define various structures (e.g., air-holes and defects). Although vertical depths of the etch holes and etch roughness control are relevant for achieving a Q value, the tolerance of Q value to variations in the fabricated holes can be increased by making the defect modes be slightly more delocalized over a few graded defect periods. Wet-etching can then be used to release the silicon layer. More specifically, the 2D photonic crystal has a lattice of air-holes and defects that form coupled microcavities 907. Similar to the example embodiments illustrated in connection with FIGS. 5-7A-7B, the sizes and locations of the air-holes and microcavities can be designed to tune the Stokes and pump modes (e.g., the cross-sectional area of the cavities in the direction perpendicular to the direction of the propagation of light can be in the range of sub-wavelength or sub-micron).

The 2D photonic crystal 901 also includes an input port 903 and an output port 905. The input port 903 can receive pump light 911, as well as Stokes light 909 (at a low amplitude). In particular, another waveguide such as the one shown in FIG. 2 can be coupled to the input port 903 to supply the combination of the pump light and Stokes light. The 2D photonic crystal 901 produces the Stokes light with a high gain factor. Hence, the 2D photonic crystal 901 functions as an amplifier. The amplification gain can be improved by integrating a p-i-n (p-type, intrinsic, n-type) junction diode with the photonic crystal as illustrated in FIG. 10.

As a further theoretical derivation, for laser oscillation, the gain condition requires the gain G_{R} to exceed the losses α for initiation of oscillation: (G_{R}-α)>0. (The other condition, the phase condition, determines the lasing frequency in a cavity.) The Raman gain G_{R} is enhanced by the Purcell factor, as illustrated in Equation (7) above, and has a Q/Vₘ dependence. The loss α has a dependence understood from the definition of

$$Q where Q {≡}^{\frac{2 π ( stored\_energy )}{Loss\_per \_cycle}} .$$

Equating G_{R} with α for the lasing threshold, the estimated dependence on the lasing threshold Pₜₕ can be derived as:

$${P}_{th} = \frac{8 {π}^{3}}{3} ( \frac{{n}_{s}^{2}}{{λ}_{s} {λ}_{p}} ) ( \frac{{A}_{p}}{{λ}_{p}^{2}} ) ( \frac{{V}_{m}}{Γ {g}_{R}} ) \frac{1}{{Q}_{s} {Q}_{p}} \qquad ( 8 )$$

where Qₛ and Qₚ are the quality factor at the Stokes and pump wavelengths, respectively, (and approximately on the same order), g_{R} the bulk Raman gain coefficient, λₛ and λₚ the Stokes and pump wavelengths respectively, Γ the modal overlap between Stokes and pump, Aₚ the pump modal area, and nₛ the effective index at Stokes wavelengths.

According to Equation (8), the lasing threshold depends on the term

$$( \frac{{V}_{m}}{{Q}^{2}} ) ( \frac{{A}_{p}}{{λ}_{p}^{2}} ) .$$

The characteristic of this threshold is similar to that derived for whispering gallery modes in microspheres, where a Vₘ/Q² dependence is also observed. For cavity line widths significantly smaller than the homogenous line width of the scattering process (when Fermi's golden rule breaks down), the above estimate, and that of Equation (7), needs to be further enhanced by an approximation using the density of states and the transition rate per mode. Likewise, in the design of the microcavity for lasing, zero-threshold lasers can be achieved, where the spontaneous emission enhancement becomes beneficial. Additionally, laser modulations at higher frequencies are also possible with the reduced mode volumes.

Based on the above described theoretical derivation, two example considerations in designing microcavities of various embodiments of present invention are: (1) to find modes which have odd symmetry about mirror planes normal to their dominant Fourier components, and (2) to smoothen the dielectric variation away from the defect. With microcavities of various embodiments of the present invention, a Vₘ˜a factor of two larger and a lower Q on order of 10⁴ can be achieved. This allows Q/Vₘ ratios on order of 6×10⁴ to 1×10⁵ μm⁻³, with Purcell enhancement factors on order of 2×10⁴. The resultant lasing threshold, based on the estimate from Equation (8), is obtained on order of 30 μW. This estimate is made based on the above Q and Vₘ values, a mode overlap integral ˜0.8, silicon bulk Raman gain coefficients, and the modal volumes and cross-sectional areas involved. This estimate, using Equation (8), does not consider further enhancements on the gain coefficient from microcavity quantum electrodynamics. Yet, with the approximations, the threshold is already immediately comparable with the lasing threshold from Raman microspheres, where the minimum lasing threshold is reported at 62 μW. With further improvements, as provided by various embodiments of the present invention, the Q and Vₘ values drop the lasing threshold to the level of a few μW. These low-thresholds allow a directly compatible on-chip laser source with tunable wavelengths in silicon electronic-photonic integrated circuits.

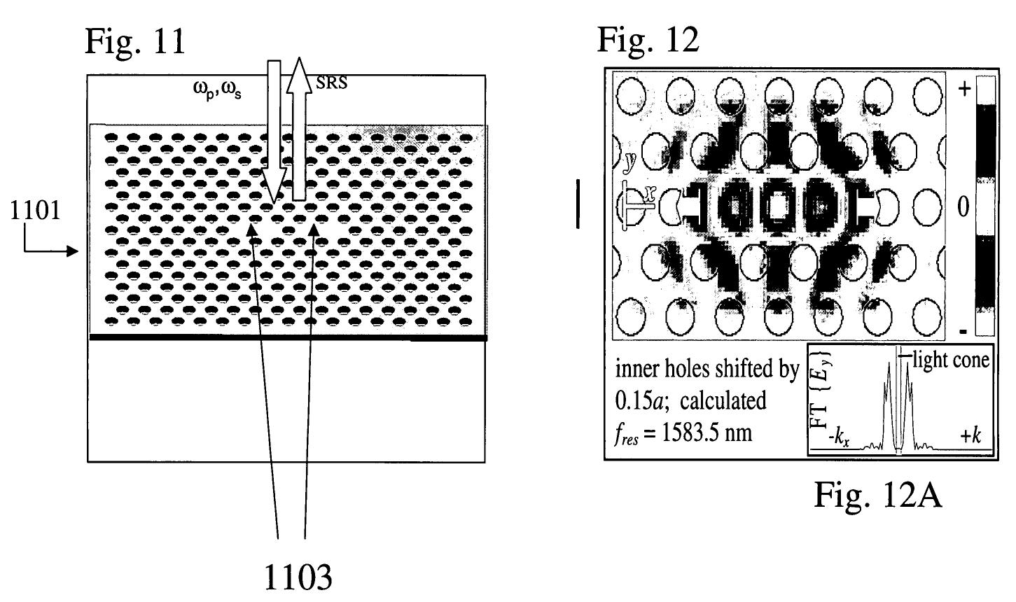

FIG. 11 illustrates an example embodiment of a 2D photonic crystal 1101 functioning as an amplifier manufactured in accordance with various embodiments of the present invention. In this example, a substantially uniform lattice of air-holes is etched from a layer of silicon formed on an insulator (e.g., a layer of oxide). The size, shape, and pattern of the air-holes are similar to the embodiments described above in connection with FIGS. 9-10. However, defects in the photonic crystal of FIG. 11 form two optically coupled microcavities 1103 without a waveguide. In operation, a tapered optical fiber (not shown), with a diameter of ˜1-2 μm, evanescently can be coupled to the microcavities 1103 when brought within a sub-wavelength distance to the surface of the photonic crystal 1101 where the microcavities 1103 are located. In response, the photonic crystal 1101 amplifies the input light (i.e., pump light) and produces Stokes light as output. The output can be collected by the same optical fiber (or a different fiber). The output is then sent to an optical detector (not shown). The near-field distance between the fiber and the chip can be varied (via a piezoelectric-controlled stage) to determine sufficiently the line width of cold-cavity (e.g., a cavity without Raman lasing taking place). The lasing threshold can be observed as a function of the near-field distance, or optically pumped with the emitted photoluminescence collected into an optical spectrum analyzer.

Having a pair of optically coupled microcavities is not required to obtain a high amplification gain. For instance, a microcavity can be formed by linear defects (e.g., linearly missing air-holes), as illustrated in FIG. 12. A single microcavity can provide Q ˜45,000 and modal volume Vₘ˜0.07 μm³. A design analysis can be performed by monitoring the Fourier components within the light cone, such as shown in FIG. 12A. When the inner pair of air holes (indicated by the arrows) is shifted outwards in the microcavity, for example, the dielectric discontinuity arising from the defect is less abrupt. This results in reduced amplitude of the Fourier components within the light cone. Smoothening the dielectric profile away from the defect (such as with a Gaussian variation in the air-hole sizes or delocalization of the mode over a few graded defect periods for example), Qs above 10⁴ can be reliably achieved. The Purcell enhancement factor for the 2D photonic crystal microcavity illustrated in FIG. 12 is on order of 10⁵.

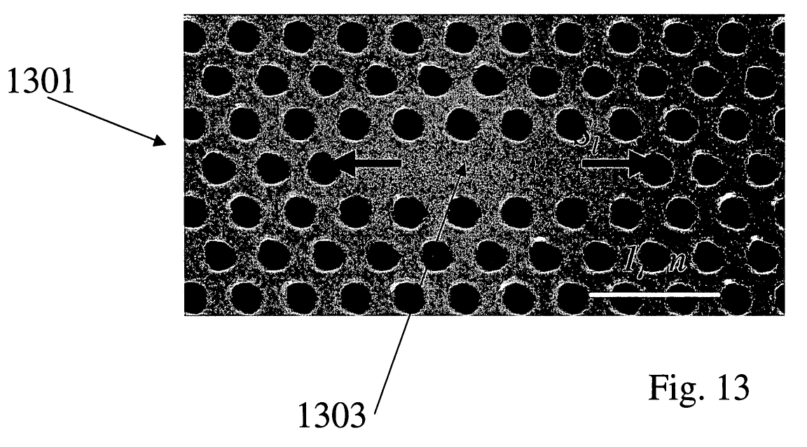

FIG. 13 illustrates another example of a photonic crystal 1301 having a single microcavity 1303, as manufactured in accordance with various embodiments of the present invention. The microcavity, again, is formed by linearly aligned missing air-holes (i.e., a defect). The microcavity can be designed numerically with MIT photonic Bands (MPB) package and the 3D FDTD method. Using MPB, the photonic band structure and the defect resonant frequencies can be obtained. With the 3D FDTD method, the defect frequencies, field profiles and Qs can be calculated. The goal of the design, similar to various other embodiments of the present invention, is to tune the frequencies of the pump mode (ƒₚᵤₘₚ) and the Stokes mode (ƒ_{Stokes}) with the spacing of 15.6 THz (Terahertz), corresponding to the optical phonon frequency in silicon for Raman scattering and lasing. The wavelengths are also tuned to operate around 1550 nm, with high Qs (on order of 10,000 or more) for at least the Stokes mode. The numerical design process is: (1) fine-tune the cavity geometry; (2) calculate resonant frequencies ƒₚᵤₘₚ and ƒ_{Stokes} with MPB; (3) calculate the lattice constant a based on the frequencies (ƒₚᵤₘₚ−ƒ_{Stokes})(c/a)=15.6 THz and calculate the wavelength λₚᵤₘₚ=a/ƒₚᵤₘₚ, λ_{Stokes}=a/ƒ_{Stokes}; and (4) calculate Qₚᵤₘₚ and Q_{Stokes} with the 3D FDTD method. The same or similar process can also be used to design microcavities for other embodiments of the present invention or for anti-Stokes cavity-enhancement, where anti-Stokes generation typically has appreciably lower scattering magnitudes.

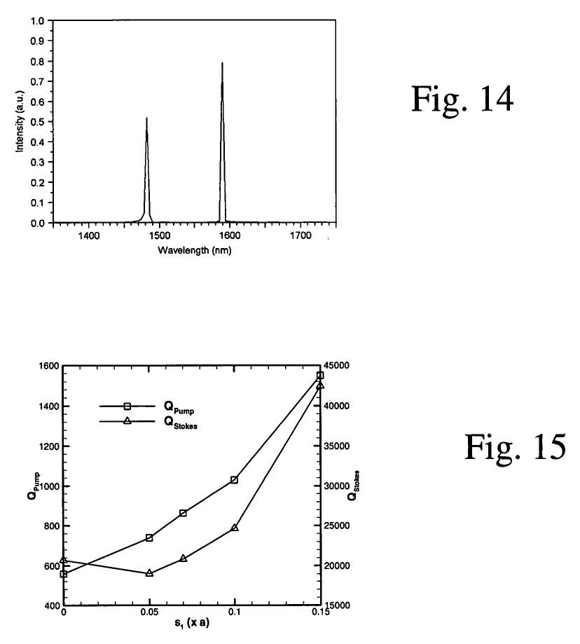

The 2D photonic crystal 1301 is an air-bridged triangular-latticed photonic crystal layer with a thickness of 0.6a, and the radius of its air-holes is 0.29a (e.g., 300 nm), where a is the lattice period. The photonic band gap in the crystal 1031 for transverse-electric-like (TE-like) modes is around 0.25˜0.32 [c/a] in frequency. For small cavities such as L3 and L4 (i.e., linearly missing three-hole structure, L3, and linearly missing four-hole structure, L4), the calculated values of a and λ are large, which may not match the telecommunication applications (around 1550 nm wavelength). For example, in the L3 cavity, S₁=0.15a, a=685 nm, λₚᵤₘₚ=2266 nm and λ_{Stokes}=2568 nm. Finally, two even modes in a single L5 cavity are used as the pump and Stokes modes for Raman lasing, respectively. Here, an L5 cavity is missing five (5) air-holes, and, therefore, the length of the cavity can be on order of several micrometers (e.g., 2.5 microns). Since the width of the cavity is on order of sub-wavelength, the surface area of the cavity can be on order of several microns-squared. FIG. 14 shows two defect modal frequencies when a Gaussian impulse is launched at the center of a particular L5 cavity.

TABLE 1
Design summary of photonic crystal L5 nanocavity
for Raman lasing in silicon.

| S₁(x a) | A(nm) | λₚᵤₘₚ (nm) | Qₚᵤₘₚ | λ_{Stokes} (nm) | Q_{Stokes} |
|---|---|---|---|---|---|
| 0 | 456 | 1592 | 560 | 1735.6 | 20693 |
| 0.05 | 414 | 1456.4 | 739 | 1575.8 | 19036 |
| 0.07 | 395 | 1395.7 | 863 | 1505 | 20843 |
| 0.10 | 376 | 1333.1 | 1030 | 1432.4 | 24642 |
| 0.15 | 342 | 1215.2 | 1550 | 1297.1 | 42445 |

Table 1 summarizes fine-tuning the values of shift S₁ of two air-holes at the edges of the microcavity. By increasing the value of S₁, the calculated lattice period a decreases and the resonant wavelength λ also decreases due to the constant optical phonon frequency. The quality factors increase because the electric field profile is close to Gaussian function and has less leakage. FIG. 15 compares the quality factors of pump mode and Stokes mode for different shifts of two air-holes, S₁=0˜0.15a. Q values are obtained by calculating modal transient energy decay with the 3D FDTD method: Q=ω₀U/P=−ω₀U/(dU/dt), where U is the stored energy, ω₀ is the resonant frequency, and P=−dU/dt is the power dissipated. For higher Q microcavities, a filter diagonalization method can be used. Qₚᵤₘₚ and Q_{Stokes} are on the order of 10³ and 10⁴, respectively. By controlling the surface roughness and fabrication steps, higher-Q microcavities can be obtained by fine-tuning the shift of additional air-holes at the cavities edge such as S₂ and S₃ or using double-hetero structure microcavities without significantly changing the effective modal volume.

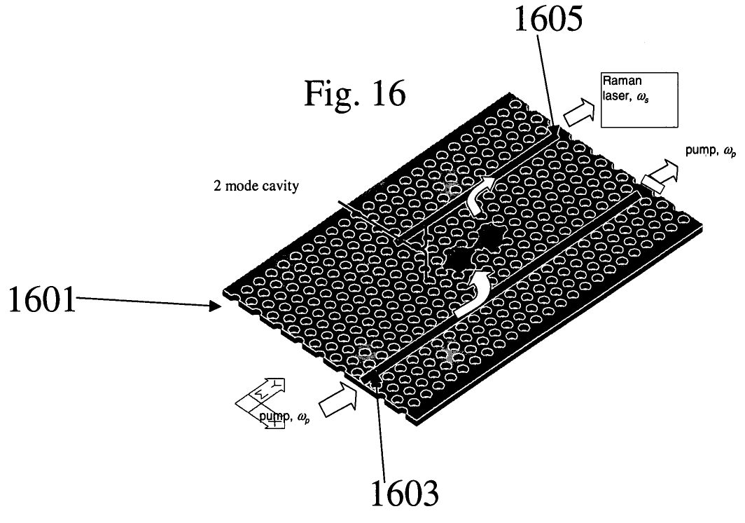

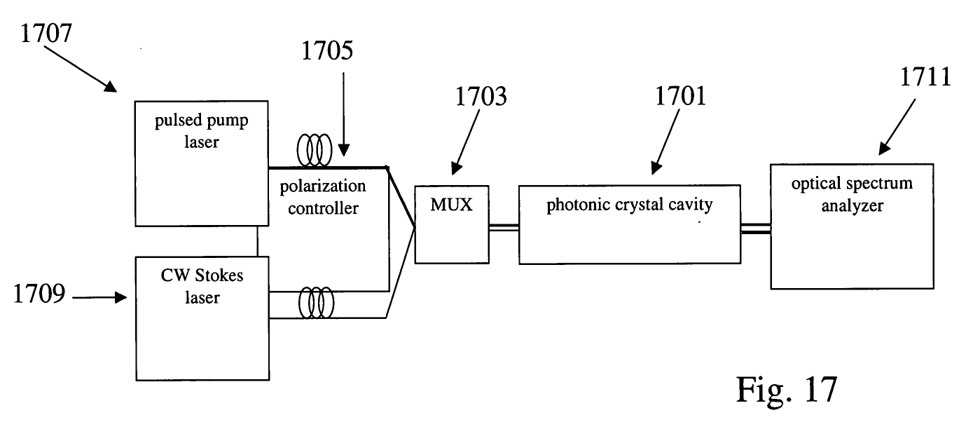

In FIG. 16, a photonic crystal 1601 manufactured in accordance with various embodiments of the present invention also includes microcavities to form a planar integrated Raman microlaser on-chip. In particular, a photonic crystal (i.e., a microlaser) 1601 fabricated with a layer of silicon on an insulator layer (not shown) can include defects that form single mode waveguides 1603, 1605. Each waveguide supports only the Stokes mode or pump mode (for example), thereby permitting generation of new lasing wavelengths with on-chip silicon. Between the single mode waveguides, a pair of coupled microcavities is formed. The cavities are two-mode cavities to support both pump and Stokes modes for Raman scattering and lasing. Variations from this configuration include an anti-Stokes generation for shorter wavelength applications and other nonlinearities through the enhanced field confinements and interaction times within the microcavity. As noted above, the planar integrated microlaser includes coupling between the Raman microcavity laser and the photonic crystal waveguides. Optimal coupling can trade off between coupling the largest (critically coupled) circulating pump power into the cavity, output coupling of the Stokes wave, and/or the Q factors of the microlaser cavity.

With the high Q/Vₘ ratios, other light scattering phenomena such as stimulated Brillouin scattering can also be achieved (although it has a 10² smaller steady-state gain in silicon and a significantly narrower gain spectrum than Raman). Higher-order Raman scattering, four-wave mixing and anti-Stokes generation are also contemplated by various embodiments of the present invention. For this reason, the photonic crystal waveguides of various embodiments of the present invention can be designed to support only a particular mode in the band gap, so as to prevent other wavelengths to appear in the Raman lasing signal. Alternatively, specific multiple modes can be intentionally designed in the band gap so that these output wavelengths can be selected as desired. In addition, self-focusing can be estimated in the various embodiments, and the optical and Raman-induced Kerr effects (field-induced birefringence) can be employed in designing various microcavities of the present invention due to the large field intensities within the sub-wavelength microcavities. Operating in this regime of high Q/Vₘ and high peak intensities, this host of nonlinearities can be actively implemented on-chip, for fundamental novel applications such as multiple-wavelength lasers or single biomolecular detection at the cavity.

With low intrinsic material losses in silicon-based photonic crystal at near-infrared wavelengths, optical losses were previously dominated by confinement losses in 2D planar photonic crystal structures. Radiation losses to the continuum modes by point-defect microcavities had earlier Q factors of several hundred. By forming microcavities in accordance with various embodiments of the present invention, radiation losses are significantly suppressed with Q factors on order of 10² or better; or equivalent, energy losses per cycle a factor of 10² smaller. These lower radiation losses, and hence longer photon confinement lifetimes in a cavity, permit low threshold powers for lasing. Low-loss photonic crystal waveguides with designs such as waveguides with guided defect modes far from the band edges or high-quality fabrication etching can achieve transmission losses as low as 1.8 dB/mm. 3D photonic crystals permit losses to be reduced down to surface roughness effects (as mirror symmetry is not broken) although 3D structures are less amendable to fabrication.

Various embodiments of the present invention differ from recently developed silica microspheres and Er³⁺-doped silica microtoroids. In contrast to silica microspheres, silicon 2D photonic crystal microcavities of various embodiments of the present invention: (1) are suitable for planar on-chip CMOS fabrication, (2) are significantly more compact (with a modal volume ˜10⁵ times smaller), and (3) can interface directly with silicon optical waveguides and other on-chip photonic-electronic circuitry.

Moreover, in contrast with Er³⁺-doped silica microtoroids, silicon 2D photonic crystal microcavities of various embodiments of the present invention: (1) have lasing tunable across selectable waveguides, (2) do not require additional laser-treatment (which was used to achieve ultra-high Q in silica or Er³⁺ implantation), and (3) have orders of magnitude faster modulation speeds due to their ˜10⁴ smaller modal volumes and not being limited by Er³⁺ lifetimes (on order 10-12 ms). The lower Q in silicon photonic crystal microcavities in comparison with the silica structures adversely affects the lasing threshold (varying at 1/Q² as first derived in Equation (8)); however, this is compensated by the 10⁴ larger bulk Raman gain coefficient in silicon and the 10⁴ to 10⁵ smaller modal volumes to bring the lasing threshold back on comparable grounds of order several to 10s of 1 W. Various embodiments of the present invention also relate to low-threshold Raman lasing in silicon 2D photonic crystal microcavities with high Q/Vₘ ratios.

For various embodiments of the present invention, in order to provide a net Raman gain, TPA induced the free-carrier absorption phenomenon can also be addressed using pulsed operations, where the carrier lifetime is much larger than the pulse width and much less than the pulse period. In particular, a photonic crystal 1701 with one or more microcavities is coupled to a multiplexer (MUX) 1703. The MUX 1703 receives its input from a polarization controller 1705 that combines inputs from a pulsed pump laser 1707 and a continuous wave (CW) Stokes laser 1709. The output from the photonic crystal 1701 is then input to an optical spectrum analyzer (e.g., a detector) 1711.

Various embodiments and advantages of the present invention are apparent from the detailed specification, and, thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described, and, accordingly, all suitable modifications and equivalents may be resorted to falling within the scope of the invention. For example, the slow speed light technique described in connection with FIG. 2 can also be used in various other embodiments with microcavities. While the foregoing invention has been described in detail by way of illustration and example of various embodiments, numerous modifications, substitutions, and alterations are possible without departing from the scope of the invention defined in the following claims.

What is claimed is:

1. A device for generating a laser beam, comprising:
a layer of photonic crystal having a lattice of air-holes with defects that form an optical waveguide with a cross-sectional area whose dimensions are in sub-wavelength ranges, wherein the cross-sectional area is perpendicular to the propagation direction of light in the waveguide, and wherein the waveguide receives pump light and outputs Stokes light through Raman scattering.

2. The device of claim 1, wherein frequencies of the pump light and the Stokes light are selected from slow group velocity modes of the pump light and Stokes light in the waveguide.

3. The device of claim 2, wherein the slow group velocity is about 1/100 of the speed of light.

4. The device of claim 1 further comprising:
a pair of optically coupled cavities, whose geometries are substantially identical to each other, formed in the waveguide, wherein the cavities are defined to cause a frequency-splitting difference between a frequency of the pump light and a frequency of the Stokes light to correspond to an optical phonon frequency in silicon for Raman scattering lasing or amplification.

5. The device of claim 4, wherein the optical phonon frequency is about 15.6 THz in single-crystal silicon at room temperature.

6. The device of claim 4, wherein the frequency of the Stokes light is tunable.

7. The device of claim 4, wherein the frequency of the Stokes light is tunable at a predetermined temperature.

8. The device of claim 4, wherein the predetermined temperature is room temperature.

9. The device of claim 2, wherein at least one cavity is formed by additional defects in the lattice of air-holes, and each cavity has a surface area on a surface of the layer of photonic crystal, wherein dimensions of the surface area are in several micro-meter ranges.

10. The device of claim 1, wherein the layer of photonic crystal is formed on an oxide layer and the layer is made from silicon.

11. The device of claim 1 further comprising:
CMOS microelectronic devices integrated with the optical waveguide.

12. The device of claim 1 further comprising:
a p-i-n (p-type, intrinsic, n-type) diode integrated with the layer of photonic crystal, to thereby achieve a continuous wave lasing in the optical waveguide.

13. The device of claim 1 further comprising:
a pulsed light pump coupled to the waveguide to supply pulsed pump light thereto.

14. A device for generating a laser beam, comprising:
a photonic crystal made from silicon having air-holes forming a pair of optically coupled cavities, whose geometries are substantially identical to each other, wherein the cavities are defined to cause a frequency-splitting difference between a frequency of pump light and a frequency of Stokes light to correspond to an optical phonon frequency in silicon through Raman scattering.

15. The device of claim 14, wherein the optical phonon frequency is about 15.6 THz in single-crystal silicon at room temperature.

16. The device of claim 14, wherein in the photonic crystal has a bar-like structure.

17. The device of claim 14, wherein the photonic crystal is a layer having a lattice of air-holes with defects that form an optic channel.

18. The device of claim 14, wherein frequencies of the pump light and the Stokes light are selected from slow group velocity modes of the pump light and Stokes light in the photonic crystal.

19. The device of claim 14, wherein the frequency of the Stokes light is tunable.

20. The device of claim 19, wherein the frequency of the Stokes light is tunable at a predetermined temperature.

21. The device of claim 19, wherein the predetermined temperature is room temperature.

22. The device of claim 14 further comprising:
CMOS microelectronic devices integrated with the photonic crystal.

23. The device of claim 14 further comprising:
a p-i-n (p-type, intrinsic, n-type) diode integrated with the photonic crystal, to thereby achieve a continuous wave lasing in the optical waveguide.

24. The device of claim 14 further comprising:
a pulsed light pump coupled to the waveguide to supply pulsed pump light thereto.

25. A device for generating a laser beam, comprising:
a layer of photonic crystal having a lattice of air-holes;
at least one cavity formed by defects in the lattice of air-holes, the cavity having a surface area on a surface of the layer, wherein dimensions of the surface area are in several micro-meter ranges, and
wherein the cavity outputs Stokes light in response to pump light through Raman scattering.

26. The device of claim 25, wherein the cavity is defined to cause a frequency-splitting difference between a frequency of the pump light and a frequency of the Stokes light to correspond to an optical phonon frequency in silicon for Raman scattering lasing or amplification.

27. The device of claim 26, wherein the optical phonon frequency is about 15.6 THz in single-crystal at room temperature.

28. The device of claim 27, wherein the at least one cavity comprises:
a pair of coupled cavities whose geometries are substantially identical to each other.

29. The device of claim 25, wherein the layer with air-holes has additional defects that form a first waveguide configured to channel the pump light and a second waveguide configured to channel the Stokes light, wherein the first and second waveguides are single mode waveguides.

30. The device of claim 29 further comprising:
a pair of cavities whose geometries are substantially identical to each other, wherein the first and second waveguides are optically coupled to the pair of cavities.

31. The device of claim 25, wherein frequencies of the pump light and the Stokes light are selected from slow group velocity modes of the pump light and Stokes light in the photonic crystal.

32. The device of claim 25, wherein the frequency of the Stokes light is tunable.

33. The device of claim 32, wherein the frequency of the Stokes light is tunable at a predetermined temperature.

34. The device of claim 32, wherein the predetermined temperature is room temperature.

35. The device of claim 25, wherein the layer of photonic crystal is formed on an oxide layer and the layer is made from silicon.

36. The device of claim 25 further comprising:
CMOS microelectronic devices integrated with the optical waveguide.

37. The device of claim 25 further comprising:
a p-i-n (p-type, intrinsic, n-type) diode integrated with the layer of photonic crystal, to thereby achieve a continuous wave lasing in the optical waveguide.

38. The device of claim 25, a pulsed light pump coupled to the waveguide to supply pulsed pump light thereto.

39. A method of manufacturing a laser device, comprising:
forming a layer of silicon; and
etching the silicon layer to form photonic crystal having a lattice of air-holes with defects that form an optical waveguide having a cross-sectional area whose dimensions are in sub-wavelength ranges, wherein the cross-sectional area is perpendicular to the propagation direction of light in the waveguide, and wherein the waveguide receives pump light and outputs Stokes light through Raman scattering.

40. The method of claim 39 further comprising:
selecting frequencies of the pump light and the Stokes light from slow group velocity modes of the pump light and Stokes light in the waveguide.

41. The method of claim 40, wherein the slow group velocity is about 1/100 of the speed of light.

42. The method of claim 39 further comprising:
forming, in the waveguide, a pair of optically coupled cavities, whose geometries are substantially identical to each other, wherein the cavities are defined to cause a frequency-splitting difference between a frequency of the pump light and a frequency of the Stokes light to correspond to an optical phonon frequency in silicon for Raman scattering lasing or amplification.

43. The method of claim 42, wherein the optical phonon frequency is about 15.6 THz in single-crystal silicon at room temperature.

44. The method of claim 40 further comprising:
forming at least one cavity is formed by additional defects in the lattice of air-holes, and each cavity has a surface area on a surface of the layer, wherein dimensions of the surface area are in several micro-meter ranges.

45. The method of claim 39 further comprising:
forming CMOS microelectronic devices integrated with the optical waveguide.

46. The method of claim 39 further comprising:
forming a p-i-n (p-type, intrinsic, n-type) diode integrated with the layer of photonic crystal, to thereby achieve a continuous wave lasing in the optical waveguide.

47. A method for manufacturing a laser device, comprising:
forming a layer of silicon; and
etching the silicon layer to form a photonic crystal having air-holes and to form a pair of optically coupled cavities, whose geometries are substantially identical to each other, wherein the cavities are defined to cause a frequency-splitting difference between a frequency of pump light and a frequency of Stokes light to correspond to an optical phonon frequency in silicon through Raman scattering.

48. The method of claim 47, wherein the optical phonon frequency is about 15.6 THz in single-crystal silicon at room temperature.

49. The method of claim 47 further comprising:
forming the photonic crystal as a bar-like structure.

50. The method of claim 47 further comprising:
forming the photonic crystal as a layer having a lattice of air-holes with defects that form an optic channel.

51. The method of claim 47 further comprising:
selecting frequencies of the pump light and the Stokes light from slow group velocity modes of the pump light and Stokes light in the photonic crystal.

52. The method of claim 47, wherein the frequency of the Stokes light is tunable.

53. The method of claim 47 further comprising:
forming CMOS microelectronic devices integrated with the photonic crystal.

54. The method of claim 47 further comprising:
forming a p-i-n (p-type, intrinsic, n-type) diode integrated with the photonic crystal, to thereby achieve a continuous wave lasing in the optical waveguide.

55. A method of manufacturing a laser device, comprising:
forming a silicon layer;
etching the silicon layer to form photonic crystal having a lattice of air-holes; and
forming at least one cavity shaped by defects in the lattice of air-holes, the cavity having a surface area on a surface of the layer, wherein dimensions of the surface area are in several micro-meter ranges, and wherein the cavity outputs Stokes light in response to pump light through Raman scattering.

56. The method of claim 55 further comprising:
forming the cavity to cause a frequency-splitting difference between a frequency of the pump light and a frequency of the Stokes light to correspond to an optical phonon frequency in silicon for Raman scattering lasing or amplification.

57. The method of claim 56, wherein the optical phonon frequency is about 15.6 THz in single-crystal at room temperature.

58. The method of claim 57 further comprising:
forming a pair of coupled cavities whose geometries are substantially identical to each other.

59. The method of claim 55 further comprising:
forming a first waveguide configured to channel the pump light; and
forming a second waveguide configured to channel the Stokes light, wherein the first and second waveguides are single mode waveguides.

60. The method of claim 59 further comprising:
forming a pair of cavities whose geometries are substantially identical to each other, wherein the first and second waveguides are optically coupled to the pair of cavities.

61. The method of claim 55 further comprising:
selecting frequencies of the pump light and the Stokes light from slow group velocity modes of the pump light and Stokes light in the photonic crystal.

62. The method of claim 55, wherein the frequency of the Stokes light is tunable.

63. The method of claim 55 further comprising:
forming CMOS microelectronic devices integrated with the optical waveguide.

64. The method of claim 55 further comprising:
forming a p-i-n (p-type, intrinsic, n-type) diode integrated with the layer of photonic crystal, to thereby achieve a continuous wave lasing in the optical waveguide.
